(19) United States
(12) Patent Application Publication
(10) Pub. No.: US 2008/0276990 A1
(43) Pub. Date: Nov. 13, 2008

(54) Substrate surface structures and processes for forming the same

(75) Inventors: Weidong Zhou, Mansfield, TX (US); Meng Tao, Colleyville, TX (US)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: BOARD OF REGENTS, UNIVERSITY OF TEXAS SYSTEM, AUSTIN, TX (US)

(21) Appl. No.: 11/801,561

(22) Filed: May 10, 2007

(51) Int. Cl. H01L 31/0216

(52) U.S. Cl. 136/261; 136/265; 427/74

(57) ABSTRACT

Structures and methods are provided for forming substrates having surface coatings thereon. In one aspect, a structure is provided including a substrate, a surface coating formed on the surface of the substrate, wherein the surface coating comprises a monolayer of dielectric particles, and a dielectric layer having a thickness of less than a height of the dielectric particles. In another aspect of the invention, a method is provided for processing a substrate including providing a substrate having a surface, exposing a solution comprising dielectric particles to the substrate surface, forming a monolayer of dielectric particles from the solution on the substrate surface, depositing a dielectric layer on the substrate surface at a thickness of less than the height of the dielectric particles, and exposing the substrate to a thermal process.

### BACKGROUND OF THE INVENTION

1. Field of the Invention

The present invention relates to the general field of optical design for light collection in solar devices. In particular, it relates to surface coatings for use on solar device surfaces.

2. Discussion of the Background

Photovoltaic (PV) solar cells convert solar energy into electricity. One of the main focuses in solar cell research is the improvement of energy conversion efficiency (from incident solar power to electric power output). As a combination of an electronic device and an optical device, the operation of a solar cell involves both electronic and optical processes. The research in optical design of solar cells includes light collection and trapping, spectrally-matched absorption, and up/down wavelength conversion.

A good optical design for light collection is vital in achieving high-performance solar cells. One of the popular optical designs for today's commercial silicon solar cells involves anisotropically-etched micrometer-scale surface textures covered with a layer of hydrogenated silicon nitride for anti-reflection. This optical design works best on single-crystalline silicon solar cells. Since the incident angle of sunlight varies during the day, a mechanical tracking device is often required to maintain surface normal incident conditions throughout the day for improved light collection and reduced fluctuations in solar electricity generation. Additionally, as the thickness of solar cells decreases drastically in next-generation solar cells, the maximum attainable short-circuit current drops sharply due to the limited absorption length and the relatively low absorption coefficient of the solar cell. A good optical design can improve cell efficiency by increased light collection and trapping.

Various optical designs have been proposed for solar cells, including bulk-optics-based light concentrators, silicon nitride and silicon dioxide surface coatings, micrometer-scale textured surfaces, nanometer-scale moth's eyes, and refractive-index-gradient surfaces, to improve cell efficiency by increased light collection and trapping. However, these designs have had less than satisfactory performance or face difficulties in manufacturing that increase production expenses. For example, the bulk optics light concentrators often involve precision machining of optical mirrors or lenses. The silicon nitride and silicon dioxide thin-film coatings only work in a limited spectral range at near-normal incident angles. The micrometer-scale surface textures involve anisotropic etching of single-crystalline silicon substrates. Anisotropic etching does not apply to thin-film silicon and non-silicon based solar cells. Moth's eye and refractive-index-gradient surfaces have been difficult to implement in current commercial solar cells.

One approach to improve performance while reducing costs and circumventing some of the manufacturing difficulties described above involves solution-based fabrication processes. Solution-based fabrication processes involve applying a liquid solution to a substrate surface followed by thermal treatment to provide a deposited material layer having desired optical properties. Solution-based fabrication processes provide an attractive approach for multiple-scale (nano to micro and macro scale) hierarchical manufacturing since the processes can be readily scaled up for large-area fabrication with inexpensive material and fabrication costs, and do not require complicated large vacuum systems as with most current fabrication processes.

Additionally, another challenge in achieving high-efficiency thin-film solar cells is the insufficient absorption of sunlight because of short optical paths imposed by the small layer thickness (around a few micrometers). This problem is especially severe in thin-film silicon solar cells due to the relatively low absorption coefficient of the indirect band gap.

Therefore, there remains a need for a structure and a process for its proper fabrication that has improved light collection and reduced costs over existing structures and processes.

### SUMMARY OF THE INVENTION

Aspects of the invention generally provide structures and methods for forming structures on substrates, for example, solar cells, having desired optical properties. In one aspect, a structure is provided including a substrate and a surface coating formed on the surface of the substrate, wherein the surface coating includes a monolayer of dielectric particles and a dielectric layer having a thickness of less than a height of the dielectric particles.

In another aspect of the invention, a method is provided for processing a substrate including providing a substrate having a surface, exposing a solution comprising dielectric particles, forming a monolayer of dielectric particles from the solution on the substrate surface, depositing a dielectric layer on the substrate surface at a thickness of less than a height of the dielectric particles, and exposing the substrate to a thermal process.

Those skilled in the art will further appreciate the above-noted features and advantages of the invention together with other important aspects thereof upon reading the detailed description that follows in conjunction with the drawings.

### BRIEF DESCRIPTION OF THE DRAWINGS

For more complete understanding of the features and advantages of the present invention, reference is now made to the detailed description of the invention along with the accompanying figures, wherein:

FIGS. 1A-1C are schematic diagrams of forming one embodiment of the structure according to one embodiment of the process described herein;

FIG. 2 is a schematic diagram of another embodiment of the structure described herein;

FIGS. 3A-3D are graphs illustrating simulated reflectivity results for two embodiments of the surface coating described herein as compared to conventional surface coatings;

FIGS. 4A-4B are schematic diagrams illustrating light pathways through one embodiment of the structure described herein;

FIGS. 5A-5B are images of one embodiment of the dielectric particles deposited on the substrate surface;

FIGS. 6A-6B are cross-sectional schematic figures and images of one embodiment of the surface coating described herein;

FIGS. 6C-6D are perspective and side view images of one embodiment of the surface coating described herein;

FIG. 7 is a graph illustrating transmittance of a quartz substrate before and after the deposition of one embodiment of the surface coating described herein; and

FIG. 8 is a graph illustrating angle-dependent transmittance of a quartz substrate before and after the deposition of one embodiment of the surface coating described herein.

### DETAILED DESCRIPTION OF THE INVENTION

Although making and using various embodiments of the present invention are discussed in detail below, it should be appreciated that the present invention provides many inventive concepts that may be embodied in a wide variety of contexts. The specific aspects and embodiments discussed herein are merely illustrative of ways to make and use the invention, and do not limit the scope of the invention.

In the description which follows like parts may be marked throughout the specification and drawing with the same reference numerals, respectively. The drawing figures are not necessarily to scale and certain features may be shown exaggerated in scale or in somewhat generalized or schematic form in the interest of clarity and conciseness.

The present invention provides for a structure and process for forming the structure for use on a substrate, which substrate can be a partially or fully formed solar cell. In one embodiment of the invention a structure includes a surface coating formed from a monolayer of dielectric particles and a dielectric layer. The surface coating may be an omni-directional anti-reflective coating (Omni-AR). The surface coating is prepared by a solution-based method.

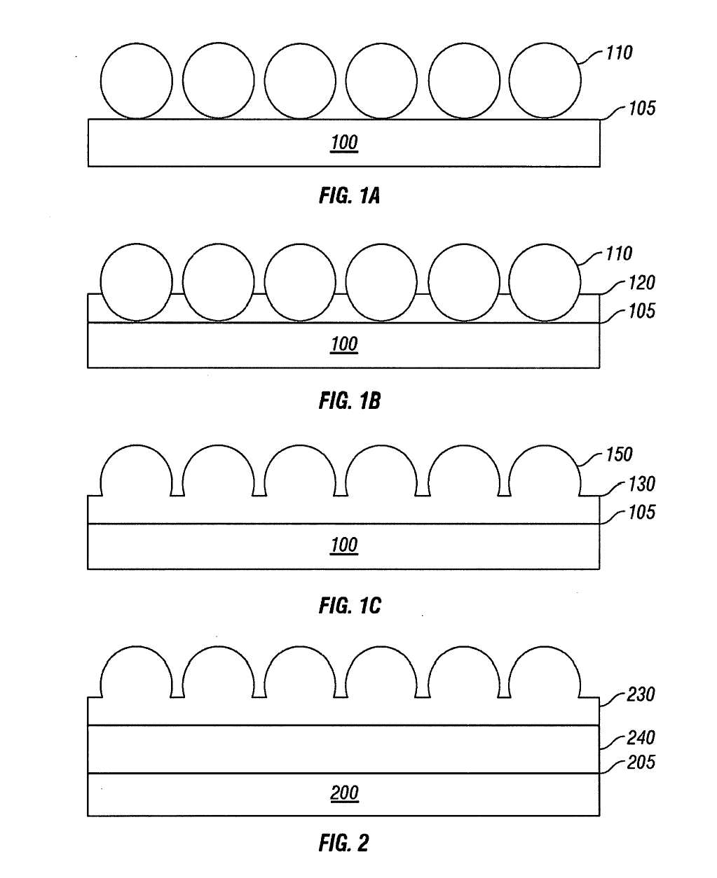

In one embodiment of the surface coating, the surface coating comprises an array of partially exposed particles of a dielectric material formed above the surface of a dielectric layer having the same or similar refractive index as the dielectric particles. This surface coating structure is fabricated from one or more solutions containing dielectric particles and/or precursors for the dielectric layer. A refractive-index-gradient dielectric layer may be disposed between the surface coating and the substrate to provide a refractive index transition between the respective refractive indices of the surface coating and the substrate. The surface coating can be directly applied to different types of solar cells made of different materials. The surface coating is described further in reference to FIGS. 1A-1C, and FIG. 2.

FIGS. 1A-1C are schematic diagrams illustrating the formation of the antireflective-coating on a substrate surface. A substrate 100 is initially provided. The substrate 100 may be made of any material, known or unknown, used in the formation of solar devices. Examples of substrate materials include single-crystalline silicon, polycrystalline silicon, amorphous silicon, copper indium diselenide, cadmium telluride, copper oxide, metals, and organic semiconductors. Suitable substrates 100 include solar cells without prior surface coating, solar cells with prior surface coating, solar cells with or without top metal contacts, textured solar cells without prior surface coating, textured solar cells with prior surface coating, textured solar cells with or without metal contacts. Examples of suitable substrates include current bulk and thin-film silicon solar cells as well as future non-silicon, organic, and quantum-dot solar cells. A metal contact layer (not shown) may be disposed on the backside of the substrate 100 or may form a backside of the substrate 100. The metal contact layer may comprises a metal materials, such as a metal selected from the group of copper, aluminum, or combination s thereof.

A layer of dielectric particles 110 is formed on a substrate surface 105 as shown in FIG. 1A. Preferably, a single layer, a monolayer, of dielectric particles 110 is formed on the substrate surface 105. Alternatively, two or more layers of dielectric particles may be formed on the substrate surface. The dielectric particles include optically transparent materials selected from the group of quartz, silica, silicon dioxide, silicon nitride, titanium dioxide, zirconium dioxide, aluminum oxide, glass, sapphire, zinc oxide, tin oxide, indium oxide, and combinations thereof. The size of the particles are preferably greater than the maximum wavelength of interest, which may be between about 300 nanometers (nm) and about 3000 nm, such as between about 300 nm and about 1500 nm. For example, a dielectric particle having a diameter of 2 μm may be used for wavelength of about 1500 nm or less. The dielectric particles 110 may have a refractive index of between about 1.0 and about 5.0, such as between about 1.0 and about 2.5, for example, about 1.5 for silicon dioxide particles.

Suitable dielectric particles have an average diameter of between about 0.1 micrometers (μm) and about 200 μm, such as between about 1 μm and about 20 μm, for example, about 2 μm. The monolayer of dielectric particles may include dielectric particles having two or more average diameters. For example, a monolayer of dielectric particles may include intermixed sets of particles with a first set of dielectric particles having an average diameter of about 1 μm and a second set of dielectric particles having an average diameter of about 2 μm. In another example, the monoloayer of dielectric particles may include a layer of particles in the nanometer range, less than about 1 μm, and a layer of micrometer-sized particles. The dielectric particles 110 may be in the shape of a sphere, a cone, a pyramid, a polyhedron, a trapezoid, an ovoid, and combinations thereof.

The dielectric particles are preferably provided in an sufficient amount to result in contact or near contact of the dielectric particles 100 to each other throughout the monolayer. The invention contemplates that the dielectric particles 110 may have a packing density between about 3×10⁵ particles/cm² and about of about 3×10⁷ particles/cm² on the substrate surface for about 2 μm sized particles. The packing density will vary according to the particle size for the one or more particle sizes used to form the monolayer of dielectric particles. One example of a monolayer of dielectric particles 110 are silicon dioxide spherical particles having an average diameter of about 2 μm, a refractive index of about 1.5, and with a packing density of about 2.5×10⁷ particles/cm².

The dielectric particles 110 may be formed from a solution including between about 0.001 weight % and about 10 weight % of dielectric particles, for example, about 0.1 weight %, i.e., 0.1 grams of particles in 100 milliliters of solution. The solution used to deposit the particles may be a solution-based process selected from the group of spin-coating, dip-coating, spray deposition, ionic layer-by-layer assembly, and combinations thereof.

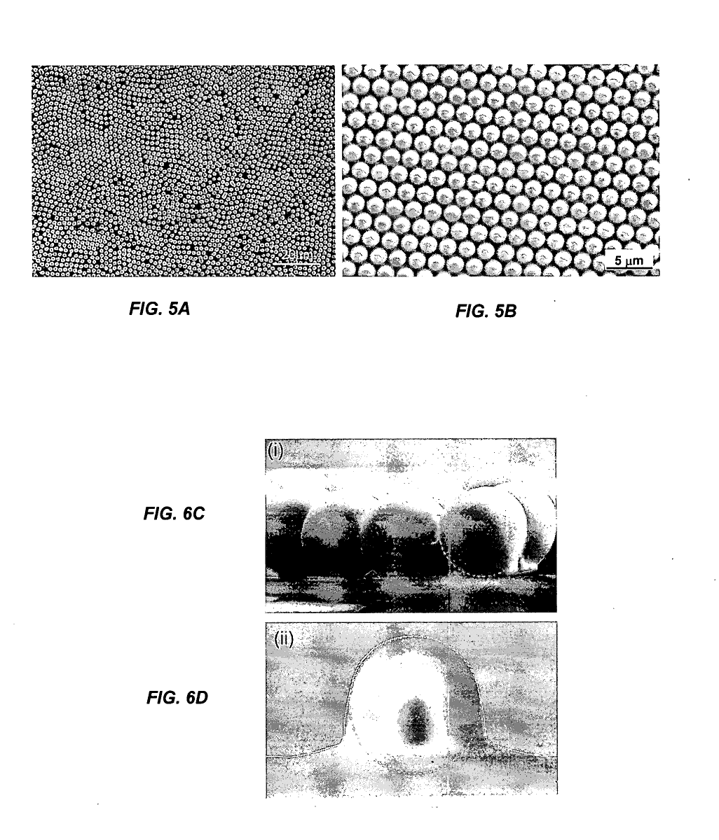

An example of a monolayer dielectric particle formation process from a solution based deposition process includes an aqueous solution containing 2.03-micrometer mono-dispersed spherical silicon dioxide particles, for example, particles identified at www.microspheres-nanospheres.com [Catalog #: 140214]. The aqueous solution was diluted with de-ionized water to a desired particle concentration of 0.1 weight % or 0.1 grams of SiO₂ particles in 100 milliliters of solution. The solution was spin coated on the surface of a silicon substrate at 250 rotations/minute for 30 seconds to form a monolayer of silicon dioxide particles on the surface. The substrate coated with particle-containing solution was exposed to a thermal process at 95° C. and 1 atmosphere for 2 minutes to remove any liquid solution. FIG. 5 illustrates the result of such a deposition process.

A dielectric layer 120 is then deposited on the substrate surface 105 as shown in FIG. 1B. The dielectric layer 120 may be a non-polymeric optically transparent material selected from the group of silicon dioxide, silicon nitride, titanium dioxide, quartz, silica, zirconium dioxide, aluminum oxide, glass, sapphire, zinc oxide, tin oxide, indium oxide, and combinations thereof. Additionally, the invention contemplates that the dielectric layer may be made from any suitable dielectric material including polymeric materials, such as polystyrene, and inorganic polymeric materials, such as silicone. The dielectric layer may have a refractive index of between about 1.0 and about 5.0, such as between about 1.0 and about 2.5, for example, 1.5, for silicon dioxide. In a preferred embodiment of the dielectric layer 120, the dielectric layer 120 has the same refractive index as the dielectric particles 110.

The dielectric layer 120 is deposited at a thickness of less than the height of the dielectric particles, such as between about 10% and about 90% of the height of the particles. Suitable dielectric layer thickness include between about 10% and about 75% of the height of the particles, for example, about 15% of the height of the particles. In another embodiment of the deposited dielectric layer, the dielectric layer 120 comprises silicon dioxide having a refractive index of about 1.5 deposited at a thickness of about 15% of the diameter of spherical dielectric particles. The dielectric layer 120 may be deposited in two or more layers to provide the desired thickness. The two or more dielectric layers of the dielectric layer 120 may have different refractive indices within the refractive index range described herein for the dielectric layer 120. The dielectric layer 120 may be deposited by spin-on glass, spray deposition, or sol-gel deposition processes, among others, of which spin-on glass and sol-gel are preferred.

In one embodiment of the deposited layer, the thickness of the dielectric layer is about 50% of the diameter of spherical particles, so the coated surface forms an array of partially exposed spherical particles that may form hemi-spherical structures above the dielectric layer. It is believed the presence of partially spherical (or hemi-spherical) particle structures 150 of the dielectric particles 110 above the dielectric layer 120 allows omi-directional (incident-angle independent) and broad-spectrum anti-reflection (Omni-AR).

The deposited dielectric layer 120 and the deposited particles 110 may then be exposed to a thermal treatment process to cure the deposited materials and form a surface coating 130 as shown in FIG. 1C. The thermal treatment process can be adjusted to produce desired optical, chemical and mechanical properties for the surface coating 130. For example, the deposited dielectric layer 120 and the deposited particles 110 may be exposed to a temperature between about 50° C. and about 300° C., such as between about 100° C. and about 150° C. for a period of time between about 1 second and about 6 hours, for example, between about 60 seconds and about 60 minutes. An example of a thermal curing process is thermally treating the deposited dielectric layer 120 and the deposited particles 110 at about 130° C. for a period of time of about 60 seconds. The thermal treatment process may further comprise two or more individual steps, which may have different temperatures and be for different periods of time. For example, the thermal treatment process may comprise a first thermal step to remove water and second thermal step to cure the deposited material.

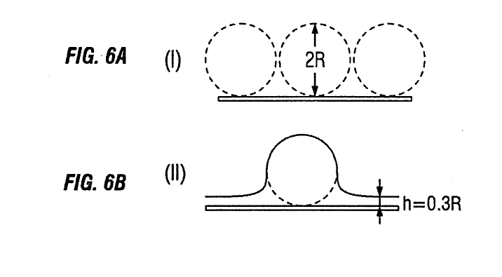

One example of the dielectric layer 120 deposition process includes a spin-on glass (SOG) solution (Honeywell Catalog #: 211), which is applied by a spin-coating process to a thickness of about 0.2 μm on a substrate having a monolayer of 2.03-micrometer spherical silicon dioxide particles. The solution was added to a substrate rotating at about 1500 revolutions/minute for about 30 seconds to produce the 0.2 μm layer. The disposed layer was then exposed to a thermal treatment in air with a first process at about 80° C. for about 60 seconds for solvent removal and then a second process at 130° C. for 60 seconds for cross-linking in the spin-on glass material. FIG. 6C illustrates a SEM photograph of the deposited dielectric layer 120 with the monolayer of dielectric particles 110.

In an alternative embodiment of the process for forming the surface coating 130 as described herein, the dielectric layer 120 may be first deposited on the substrate surface 105 from a solution and then a monolayer of dielectric particles 110 are deposited on the dielectric layer in a liquid state to partially immerse the particles in the dielectric layer. The deposited dielectric layer 120 and dielectric particles 110 are then exposed to a thermal treatment to form the surface coating 130.

In another alternative embodiment of the process for forming the surface coating 130 as described herein, the dielectric layer 120 and the dielectric particles 110 are deposited or formed on the substrate surface 105 at the same time. The concurrent deposition process may utilize separate solutions for the dielectric layer 120 and the dielectric particles 110, or may use a single solution, such as a solution of dielectric particles 120 dispersed in a sol-gel solution or spin-on glass solution. The deposited dielectric layer 120 and dielectric particles 110 are then exposed to a thermal treatment to form the surface coating 130.

It is believed that the performance of the surface coating can be controlled by using dielectric particles of different sizes, changing the refractive index of the dielectric particles, changing the packing density of the micrometer-scale dielectric particles, varying the thickness of the dielectric layer, and changing the refractive index of the dielectric layer. For example, effective dielectric particle sizes are usually larger than the longest wavelength of the spectral range of interest as larger particle sizes can extend the spectral range for longer wavelengths. It is believed that infrared light from solar radiation can be more effectively coupled into a solar cell as dielectric particle size increases, which is typically undesirable. Additionally, it is believed that a higher packing density of particles is desirable for lower reflectivity, since the flat regions between particles do not reduce surface reflection. It is further believed that a dielectric layer thicker than the radius of the spherical particles reduces the range of incident angle in which the surface coating described herein is effective. Additionally, the optimum refractive indices of the dielectric particles and dielectric layer are determined by the refractive index of the substrate.

FIG. 2 is a schematic side view of an alternative embodiment with a refractive index gradient layer 240 disposed on the substrate surface 205 prior to the deposition of the surface coating 230. The refractive index gradient layer 240 comprises a material providing a refractive index transition between the refractive index of the substrate 200 and the refractive index of the dielectric layer and dielectric particles of the surface coating 230. The refractive index gradient layer 240 (refractive-index-gradient dielectric layer) may provide a refractive index range between about 1.0 and about 5.0, for example, between about 1.5 and about 4.0. For example, the refractive index gradient layer 240 may provide a refractive index of 2. Alternatively, the refractive index gradient layer 240 may provide a refractive index of 4 at first portion of the refractive index gradient layer 240, such as near a substrate, and a refractive index of 1.5 to 2 at a second portion of the refractive index gradient layer 240, such as near the surface coating described herein. Suitable materials for the refractive gradient layer 240 are selected from the group of silicon dioxide, titanium dioxide, aluminum oxide, and combinations thereof.

The refractive index of the refractive gradient layer 240 may be provided at a desired refractive index by mixing a plurality of refractive gradient layer 240 materials with different refractive indices. For example a desired refractive index may be made by mixing silicon dioxide, which has a refractive index of 1.5, and titanium dioxide, which has a refractive index of 2.9, in a desired ratio. For example, if silicon dioxide and titanium dioxide are mixed to form refractive gradient layer 240, a ratio of silicon oxide to titanium oxide of between about 100:1 and about 1:100, may be used for producing refractive indices greater than about 1.5 and less than about 2.9.

Alternatively, the refractive index gradient layer 240 may comprise two or more layers with each layer having a different refractive index. In one embodiment of the multi-layer refractive index gradient layer, an initial layer is deposited on the substrate surface having a refractive index between about 1.5 and about 5.0, for example, between about 2.0 and about 4.0 and a second layer disposed adjacent to the surface coating having a refractive index between about 1.0 and about 4.0, for example, between about 1.5 and about 2.5. This embodiment of the refractive-index-graded layer 240 can be made from a multiple-layer structure composed of materials with different refractive indices, or from a mixture of, for example, titanium dioxide and silicon dioxide. Silicon dioxide has a refractive index of 1.5 and titanium dioxide has a refractive index of 2.9. Mixing titanium dioxide and silicon dioxide in different ratios will allow the formation of layers with different refractive indices.

It is believed that the index gradient layer in conjunction with the surface coating can minimize surface reflectivity in wide ranges of incident angle and wavelength by providing a transition material having a refractive index between that of the surface coating and the substrate.

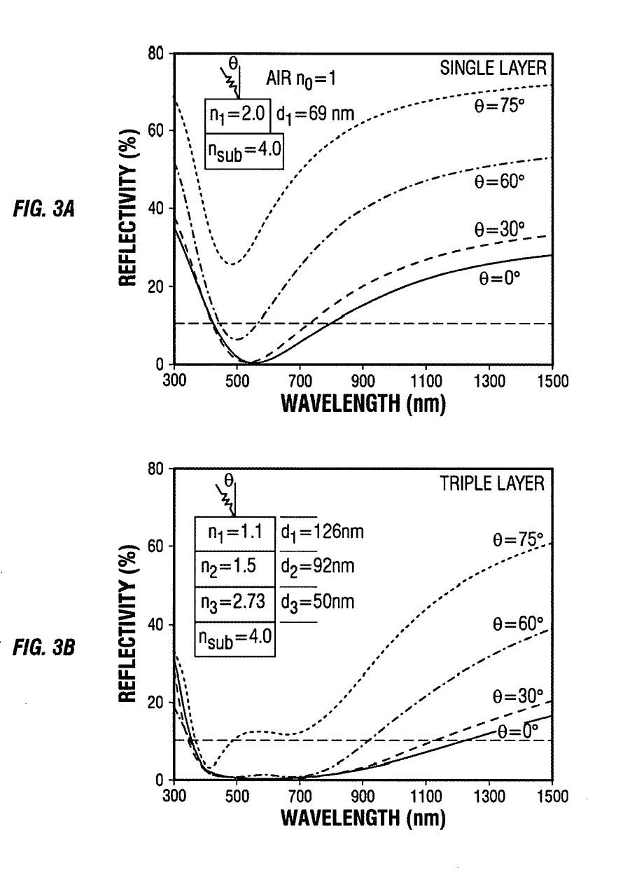

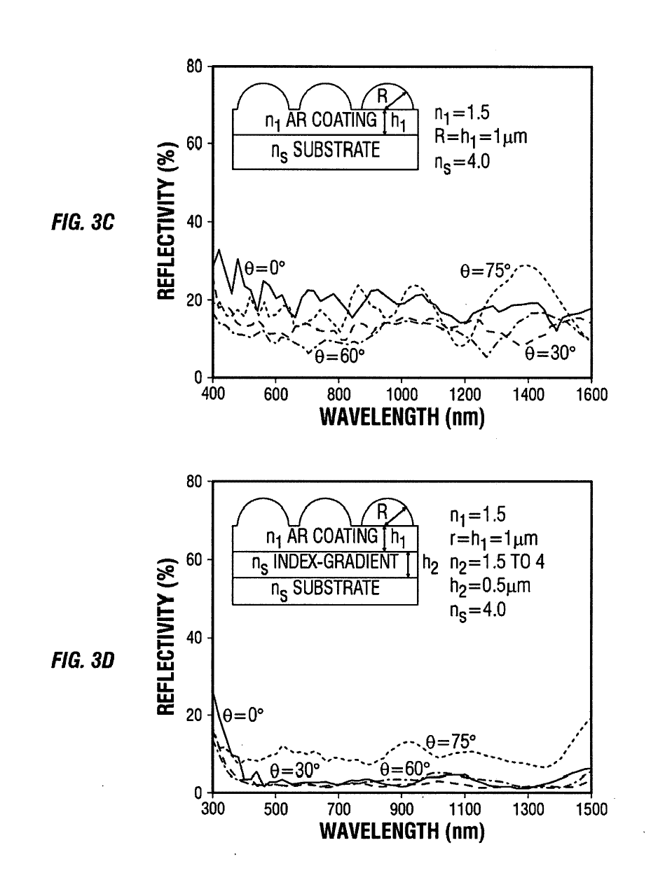

FIGS. 3A-3D are graphs showing simulated reflectivity results for surface coatings prepared according to the processes described herein as compared to conventional single-layer and multiple-layer surface coatings. The simulation used a simulator developed by KJInnovations, which can compute optical diffraction based on a generalized variant of rigorous coupled-wave diffraction theory. The surface coatings described herein were observed for low surface reflectivity in wide ranges of incident angle and wavelength. The spectral range of interest is from about 300 nanometers to about 3000 nanometers for solar cells, such as from about 300 nanometers to about 1500 nanometers.

FIGS. 3A and 3B comprise conventional single-layer and three-layer surface coatings having optimum refractive index and thickness. FIG. 3A illustrates that a conventional single-layer surface coating has a reflectivity of above 20% for a significant portion of the spectral range of interest at an incident angle of 0°, and the reflectivity increases substantially with incident angle to have reflectivity above 50% for significant portions of the spectral range of interest at incident angles of 60° or more. FIG. 3B illustrates the same phenomena for a conventional triple-layer surface coating with the reflectivity of the multiple-layer coating increasing above 50% at large incident angles and long wavelengths. The observed change in reflectivity over incident angle and wavelength indicates that the reflectivity is wavelength and incident angle dependent.

In contrast, FIG. 3C illustrates that the reflectivity for the surface coating (refractive index, n₁, of 1.5) of the invention disposed on a silicon substrate (refractive index, n_{S}, of 4.0) was observed to have a reflectivity of about 30% or below over the spectral range of interest at incident angles between 0° and 75°. The surface coating of FIG. 3C comprises a silicon oxide layer having a refractive index of 1.5 and silicon oxide spherical particles, radius of about 1 μm, having a refractive index of 1.5 with about 50% of the respective silicon oxide particles disposed above the surface of the dielectric layer. The observed lack of change in reflectivity over incident angle and wavelength indicates that the reflectivity is wavelength and incident angle independent for structures formed using the surface coating described herein.

In FIG. 3D, a structure including a refractive index gradient dielectric layer (refractive index, n₂, changing from 1.5 to 4.0) disposed between the surface coating (refractive index, n₁, of 1.5) and a silicon substrate (refractive index, n_{S}, of 4.0) was observed to have a reflectivity of below 5% over the spectral range of interest at incident angles between 0° and 60° and a reflectivity of below 20% over the spectral range of interest at incident angles between 0° and 75°. The surface coating of FIG. 3D comprises a silicon oxide layer having a refractive index of 1.5 and silicon oxide spherical particles, radius of about 1 μm, having a refractive index of 1.5 with about 50% of the respective silicon oxide particles disposed above the surface of the dielectric layer with the refractive index gradient dielectric layer having a thickness of about 0.5 μm. Further it has been conventionally observed that a reduction in reflection at all wavelengths and all incident angles can lead to increased absorption of solar power.

It is believed that the ability to collect direct incident sunlight as well as diffusive sunlight with minimal reflection for a wide range of incident angle from surface normal to 60°-plus allows for a more efficient solar cell as such an ability to effectively collect sunlight in a wide range of incident angle allows efficient collection of sunlight all day long and under all weather conditions without the need for an optical tracking device for proper alignment of the solar cell with incident sunlight. Since it has been estimated that the diffuse component of sunlight accounts for 10% to 20% of the total solar energy on a horizontal surface, and on a cloudy day, 100% of the sunlight is diffuse, the structures formed using the surface coating described herein are believed to be more efficient in collecting sunlight under all weather conditions.

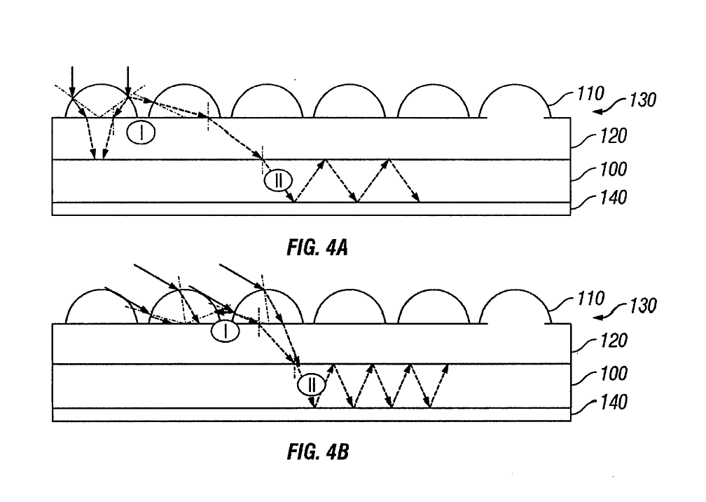

The surface coating also increases the effective optical paths of the collected light by multiple incident paths and increased total internal reflection as shown in FIGS. 4A-4B. It is believed that an increase in the optical path to more readily retain the light within a solar cell increases the efficiency in absorbing sunlight. It is believed that light striking the surface coating may experience two effects. A significant portion of the light experiences a second chance of incidence after refraction in the surface coating 130 (I), at an incident angle of about 0° as shown in FIG. 4A. Incident light from second incidence and from off-normal incidence, such as at incident angle of about 60° as shown in FIG. 4B, is retained inside the semiconductor layer 100 (II) with multiple absorption paths due to total internal reflection as shown in FIGS. 4A-4B. The total internal reflection occurs due to the presence of the low index surface coating 130 on top, such as silicon dioxide, and the metal contact layer 140 at bottom. Both processes are believed to improve the efficiency of the solar cell having the surface coating described herein compared to cells using conventional surface coatings.

FIGS. 5A-5B are scanning electron microscopy (SEM) images of a monolayer of 2.03-micrometer silicon dioxide spherical particles spin-coated on a silicon substrate. It can be seen that the spherical particles are arranged into multiple domains (FIG. 5A) with each domain close packed (FIG. 5B). The monolayer of spherical particles was deposited by an aqueous solution containing 2.03-micrometer mono-dispersed spherical silicon dioxide particles from www.microspheres-nanospheres.com [Catalog #: 140214], the aqueous solution was diluted with de-ionized water to a desired particle concentration of 0.1% weight volume (0.1 grams of SiO₂ particle in 100 milliliters of solution), and the solution was spin coated on the surface of a silicon wafer at 250 rotations/minute for 30 seconds. These conditions allow the formation of a monolayer of silicon dioxide particles on the surface. The substrate coated with SiO₂-containing solution was baked on a hot plate in air at 95° C. for 2 minutes.

FIGS. 6A-6D illustrate cross-sectional views and SEM images of a monolayer of 2.03-micrometer silicon dioxide spherical particle disposed on a glass substrate as shown in 6A and 6C and a monolayer of 2.03-micrometer silicon dioxide spherical particles partially immersed in a spin-on glass layer on a quartz substrate as shown in FIGS. 6B and 6D. The thickness of the spin-on glass layer (h) can be controlled for a desired surface coating profile. Ideally the thickness of the glass layer should be equal to the radius of the dielectric particles (h=R) to have a perfect hemi-spherical surface structure. However, any derivation of the actual dielectric layer thickness from the ideal value is still acceptable with a possibly-reduced anti-reflective effect.

In the example illustrated in FIGS. 6A-6B, the dielectric layer is deposited to a thickness of about 30% of the radius, or 15% of the diameter, of the silicon dioxide particles. It can also be observed that there is a “shoulder region” between the partially-immersed spherical particles and the spin-on glass layer, due to capillary effects. The dielectric layer was deposited from spin-on-glass (SOG) solution obtained from Honeywell [Catalog #: 211] by a spin coated process on a substrate coated with a monolayer of silicon dioxide particles (as deposited with reference to FIGS. 5A-B) to make these particles partially immersed in a dielectric film. The spin speed used here for SOG coating was 1500 rotations/minute for 30 seconds, which resulted in film thickness of 0.2 μm. The substrate was finally baked in air on hot plates at 80° C. for 60 seconds for solvent removal and then at 130° C. for 60 seconds for SOG cross-link.

FIG. 7 shows a normal-incident total transmittance measurement by a UV-vis spectrophotometer. The measurement was performed using a JASCO V-570 spectrophotometer from JASCO, Inc of Easton, Md., with an integrating sphere. The surface coating described herein comprises a monolayer of 2.03-micrometer silicon dioxide spherical particles partially immersed in a spin-on glass layer having a thickness of about 0.2 micrometers. For comparison, the total transmittances of the quartz substrate without any coating, the quartz substrate coated with spin-on glass only and the quartz substrate coated with silicon dioxide spherical particles only were also measured. The surface coating described herein improved the transmittance by about five percentage points at shorter wavelengths, such as 300 nanometers, and about one percentage point at longer wavelengths, such as about 1300 nanometers. It was also observed that spin-on glass alone or micrometer-scale spherical particles alone did not improve the transmittance.

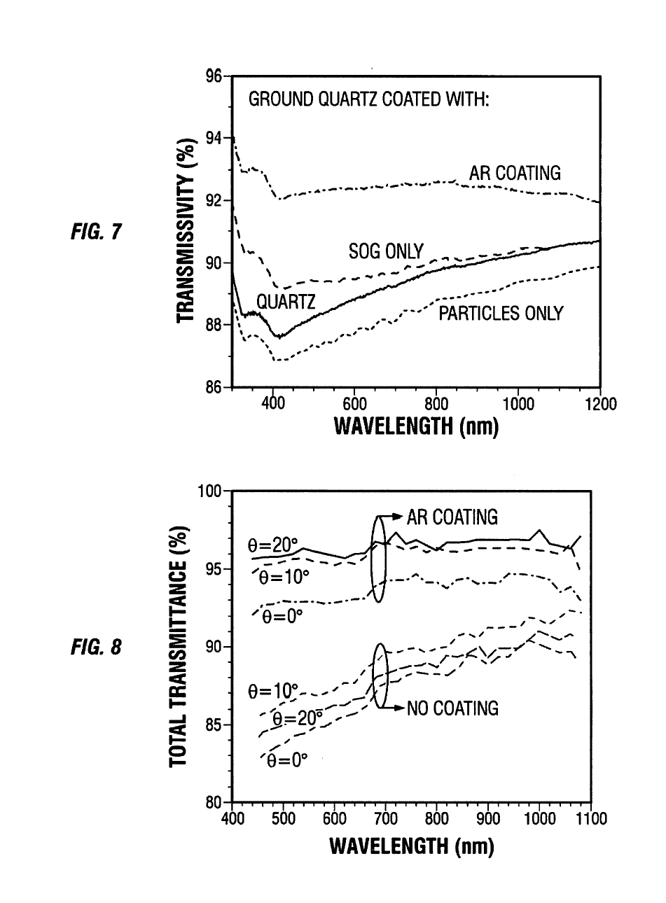

FIG. 8 shows an incident-angle dependent transmittance measurement before and after deposition of the surface coating on a quartz substrate as described in FIG. 7. The surface coating comprises an array of 2.03-micrometer diameter spherical particles partially immersed in a spin-on glass layer. Incident angles between 0° and 20° were measured. The results illustrate an improvement in total transmittance by the surface coating as incident angles deviate from normal incidence. The transmittance is improved by over eight percentage points at short wavelengths and about four percentage points at about 1000 nanometers. Greater than 90% total transmittance can be obtained for the entire spectral range and incident angles tested for the surface coating. Based on the trend illustrated in FIG. 8, it is believed that similar improvement in transmittance will occur for larger incident angles, based on the simulated results in FIGS. 3A-3D.

It is believed that the surface coating described herein will result in improved optical design for solar cells. The surface coating has been observed to reduce surface reflectivity over a broad spectrum, reduce surface reflectivity over a wide range of incident angle, and provide a surface coating that is not substrate specific. The processes described herein allow the surface coating to be fabricated by solution-based methods so the surface coating has an intrinsically lower cost compared to prior antireflective coatings for solar cell fabrication and the surface coating is suitable for large-area solar cell fabrication.

While specific alternatives to steps of the invention have been described herein, additional alternatives not specifically disclosed but known in the art are intended to fall within the scope of the invention. Thus, it is understood that other applications of the present invention will be apparent to those skilled in the art upon reading the described embodiment and after consideration of the appended claims and drawing.

What is claimed is:

1. A structure, comprising:
a substrate;
a surface coating formed on the surface of the substrate, wherein the surface coating comprises:
a monolayer of dielectric particles; and
a dielectric layer having a thickness of less than a height of the dielectric particles.

2. The structure of claim 1, wherein the dielectric particles are selected from the group of quartz, silica, silicon dioxide, silicon nitride, titanium dioxide, zirconium dioxide, aluminum oxide, glass, sapphire, zinc oxide, tin oxide, indium oxide, and combinations thereof.

3. The structure of claim 1, wherein the dielectric particles comprise a shape selected from the group consisting of a sphere, a cone, a pyramid, a polyhedron, a trapezoid, an ovoid, and combinations thereof.

4. The structure of claim 1, wherein portion of the dielectric particles is exposed above the surface of the dielectric layer.

5. The structure of claim 1, wherein the dielectric layer has a thickness between about 10% and about 90% of the height of the dielectric particle.

6. The structure of claim 1, wherein the dielectric particles have a first refractive index between about 1.0 and about 5.0 and the dielectric layer has a second refractive index between about 1.0 and about 5.0.

7. The structure of claim 6, wherein the first refractive index and the second refractive index of the dielectric layer are the same.

8. The structure of claim 1, wherein the substrate has a refractive index between about 1.5 and about 5.0 and the surface coating has a refractive index of between about 1.0 and 2.5.

9. The structure of claim 1, further comprising a refractive-index-gradient dielectric layer disposed between the substrate surface and the surface coating.

10. The structure of claim 9, wherein the refractive-index-gradient dielectric layer provides a refractive index range between about 1.5 and about 3.5.

11. The structure of claim 9, wherein the refractive-index-gradient dielectric layer comprises two or more layers with an initial deposited layer having a larger refractive index than a final deposited layer.

12. The structure of claim 1, wherein the surface coating has a reflectivity of less than 20% between about 300 nm and about 1500 nm at a incident angle between about 0° and about 75°.

13. The structure of claim 1, wherein the particles have a diameter greater than a wavelength of light to be collected on the substrate surface.

14. A method for processing a substrate, comprising:
providing a substrate having a surface;
exposing a solution comprising dielectric particles to the substrate surface;
forming a monolayer of dielectric particles from the solution on the substrate surface;
depositing a dielectric layer on the substrate surface at a thickness of less than a height of the dielectric particles; and
exposing the substrate to a thermal process.

14. The method of claim 14, wherein the dielectric particles are selected from the group of quartz, silica, silicon dioxide, silicon nitride, titanium dioxide, zirconium dioxide, aluminum oxide, glass, sapphire, zinc oxide, tin oxide, indium oxide, and combinations thereof.

15. The method of claim 14, wherein the dielectric particles comprise a shape selected from the group consisting of a sphere, a cone, a pyramid, a polyhedron, a trapezoid, an ovoid, and combinations thereof.

16. The method of claim 14, wherein the dielectric layer has a thickness between about 10% and about 90% of the height of the dielectric particle.

17. The method of claim 14, wherein forming the monolayer dielectric particles comprises a process selected from the group of spin-coating, dip-coating, spray deposition, or ionic layer-by-layer assembly.

18. The method of claim 14, wherein the dielectric particles have a first refractive index between about 1.0 and about 5.0 and the dielectric layer has a second refractive index between about 1.0 and about 5.0.

19. The method of claim 18, wherein the first refractive index and the second refractive index of the dielectric layer are the same.

20. The method of claim 14, wherein a portion of the dielectric particles is exposed above the surface of the dielectric layer.

21. The method of claim 14, wherein the dielectric layer is deposited by a process selected from the group of spin-on glass deposition, spray deposition, or sol-gel deposition.

22. The method of claim 14, wherein the deposition of the dielectric layer is performed prior to the forming of the monolayer of dielectric particles.

23. The method of claim 14, wherein the deposition of the dielectric layer is performed after the forming of the monolayer of dielectric particles.

24. The method of claim 14, wherein the deposition of the dielectric layer and the forming of the monolayer of dielectric particles are performed at the same time.

25. The method of claim 14, further comprising depositing a refractive-index-gradient dielectric layer prior to the deposition of the dielectric layer or the deposition of the monolayer dielectric particles.

26. The method of claim 25, wherein the refractive-index-gradient dielectric layer provides a refractive index range between about 1.5 and about 3.5.

27. The method of claim 14, wherein the thermal process comprises applying a temperature between about 50° C. and about 300° C. for a period of time between about a 1 second and about a 6 hours.

28. The method of claim 14, wherein the thermal process comprises one or more steps.

29. The method of claim 14, wherein the thermal process comprises thermally treating the monolayer of dielectric particles and the dielectric layer in separate processing steps.
